(19) United States
(12) Patent Application Publication
(10) Pub. No.: US 2026/0144130 A1
(43) Pub. Date: May 21, 2026

(54) SEMICONDUCTOR PACKAGE

(71) Applicant: SAMSUNG ELECTRONICS CO., LTD., Suwon-si (KR)

(72) Inventors: Dohee KIM, Suwon-si (KR); Ki-Hong JEONG, Suwon-si (KR)

(73) Assignee: SAMSUNG ELECTRONICS CO., LTD., Suwon-si (KR)

(21) Appl. No.: 19/182,907

(22) Filed: Apr. 18, 2025

(30) Foreign Application Priority Data
Nov. 18, 2024 (KR) 10-2024-0164014

(51) Int. Cl. H01L 23/00; H01L 23/31; H01L 25/18

(52) U.S. Cl. CPC H10W 74/124; H10W 90/00; H10W 72/859; H10W 72/877; H10W 72/884; H10W 90/24; H10W 90/728; H10W 90/732; H10W 90/734; H10W 90/752; H10W 90/754

(57) ABSTRACT

A semiconductor package includes a substrate, a semiconductor chip disposed on the substrate and electrically connected to the substrate, an encapsulant covering at least a portion of the semiconductor chip, the encapsulant including a groove portion at least partially disposed above the semiconductor chip, a passive element disposed at least partially within the groove portion, and a conductive pillar embedded at least partially in the encapsulant and electrically connecting the semiconductor chip and the passive element.

### CROSS-REFERENCE TO RELATED APPLICATION

This application claims priority to and the benefit of Korean Patent Application No. 10-2024-0164014 filed at the Korean Intellectual Property Office on Nov. 18, 2024, the entire contents of which are incorporated herein by reference.

### TECHNICAL FIELD

The present disclosure relates to a semiconductor package.

### BACKGROUND

In the semiconductor package industry, a multi-layer ceramic capacitor (MLCC) may be mounted side by side with a semiconductor chip on a substrate to improve signal quality, and the MLCC may be connected to the semiconductor chip through the substrate.

When mounting the MLCC on a substrate, there is a problem in that mounting space for the MLCC is required and it may be difficult to utilize the MLCC mounting space as a wiring space.

### SUMMARY

In one aspect, some embodiments provide a semiconductor package capable of improving signal quality without increasing size.

In another aspect, some embodiments provide a semiconductor package capable of securing freedom in wiring design.

In another aspect, some embodiments provide a semiconductor package having low inductance by connecting passive elements and a semiconductor chip with a short electrical path.

Some embodiments provide a semiconductor package including a substrate, a semiconductor chip disposed on the substrate and electrically connected to the substrate, an encapsulant covering at least a portion of the semiconductor chip, the encapsulant including a groove portion at least partially disposed above the semiconductor chip, a passive element disposed at least partially within the groove portion, and a conductive pillar embedded at least partially in the encapsulant and electrically connecting the semiconductor chip and the passive element.

Some embodiments provide a semiconductor package including a substrate; a semiconductor chip disposed on the substrate and including a first connection pad, a second connection pad, and a third connection pad; an encapsulant covering at least a portion of the semiconductor chip, the encapsulant including a groove portion, at least a portion of the groove portion is disposed above the semiconductor chip; a passive element disposed at least partially within the groove portion and including a first external electrode and a second external electrode; a first conductive wire embedded at least partially in the encapsulant and electrically connecting the first connection pad to the substrate; a first conductive pillar embedded at least partially in the encapsulant and electrically connecting the second connection pad to the first external electrode; and a second conductive pillar embedded at least partially in the encapsulant and electrically connecting the third connection pad to the second external electrode.

Some embodiments provide a semiconductor package including a substrate; a chip stacking structure disposed on the substrate and including a plurality of stacked first semiconductor chips; an encapsulant covering at least a portion of the chip stacking structure, the encapsulant including a groove portion at least partially disposed above the chip stacking structure; a passive element disposed at least partially within the groove portion; and a conductive pillar embedded at least partially in the encapsulant and electrically connecting one of the first semiconductor chips to the passive element.

### BRIEF DESCRIPTION OF THE DRAWINGS

FIG. 1 is a cross-sectional view of a semiconductor package according to an embodiment.

FIG. 2 is an enlarged view of region A of FIG. 1.

FIG. 3 is a top view of the semiconductor package shown in FIG. 1.

FIG. 4 is an enlarged view of region B of FIG. 3.

FIG. 5 is a partial cross-sectional view taken along line I-l′ of FIG. 4.

FIG. 6 is a cross-sectional view of a semiconductor package according to another embodiment.

FIG. 7 is a cross-sectional view of a semiconductor package according to another embodiment.

FIGS. 8 to 12 are manufacturing process diagrams of the semiconductor package shown in FIG. 1.

### DETAILED DESCRIPTION

The present disclosure will be described in detail hereinafter with reference to the accompanying drawings, in which embodiments of the present disclosure are shown. As those skilled in the art would realize, the described embodiments may be modified in various different ways, all without departing from the scope of the present disclosure.

The drawings and description are to be regarded as illustrative in nature and not restrictive, and like reference numerals designate like elements throughout the specification.

Further, since sizes and thicknesses of constituent members shown in the accompanying drawings may be arbitrarily given to facilitate understanding and ease of description, the disclosure is not limited to the illustrated sizes and thicknesses. In the drawings, the thicknesses of layers and regions are exaggerated for clarity. In the drawings, to facilitate understanding and ease of description, the thicknesses of some layers and regions may be exaggerated.

Throughout the specification, the term “connected” may mean not only “directly connected,” but also “indirectly connected” with another element in between. In a similar perspective, this includes being “physically connected,” as well as being “electrically connected.”

It should be understood that when an element such as a layer, film, region, or substrate is referred to as being “on” another element, it may be directly on the other element or intervening elements may also be present. In contrast, when an element is referred to as being “directly on” another element, there are no intervening elements present. Further, being “on” or “above” a reference element means being above or below the reference element, and it may not necessarily mean being positioned “on” or “above” it in a direction opposite to gravity.

In addition, unless explicitly stated to the contrary, the word “comprise” and variations such as “comprises” and “comprising” should be understood to imply the inclusion of stated elements but not the exclusion of any other elements.

In addition, the phrase “on a plane” means a view from a position above the object (e.g., from the top), and the phrase “in a cross-section” means a view of a cross-section of the object which is vertically cut from the side.

In addition, throughout the specification, although the terms “first,” “second,” and the like are used to explain various components, the components are not limited to such terms but are only used to distinguish one component from another component. Accordingly, a configuration referred to as the first component in a certain part of the specification may also be referred to as the second component in other parts of the specification.

As used herein, singular forms are intended to include plural forms unless the context clearly indicates otherwise. For example, “insulating layer” may be used to mean not just a single insulating layer, but a plurality of insulating layers, such as two, three, or more.

Additionally, throughout the specification, references to directions such as upper surface, upper side, upper part, lower surface, lower side, and lower part are intended to aid description and understanding with reference to the drawings.

Hereinafter, a semiconductor package according to embodiments of the present disclosure will be described with reference to the drawings.

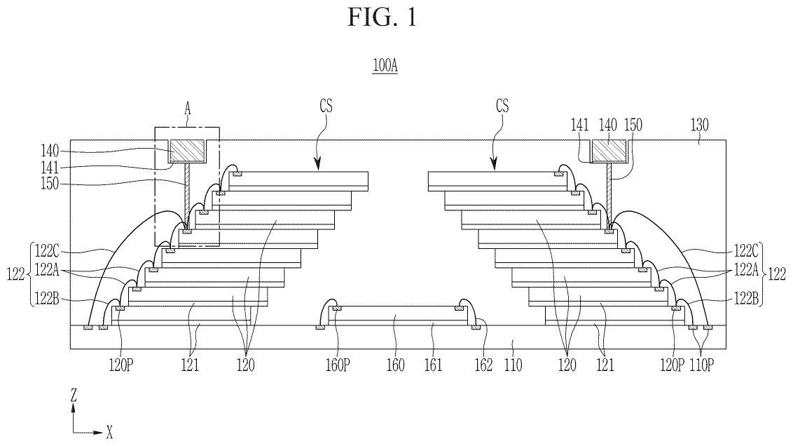

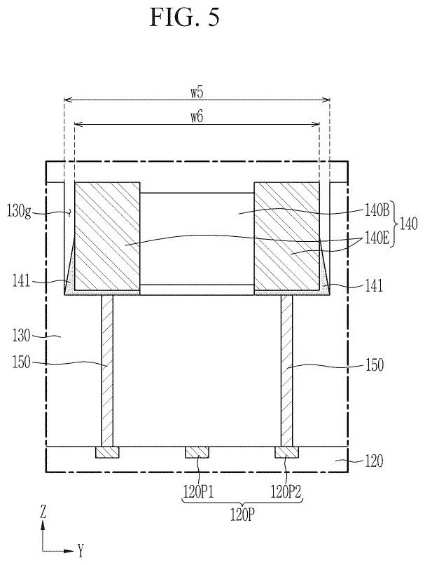

Referring to FIGS. 1-5, a semiconductor package 100A according to an embodiment may include a substrate 110, a chip stacking structure CS, an encapsulant 130 having a groove portion 130g, a passive element 140, a conductive pillar 150, and a semiconductor chip 160.

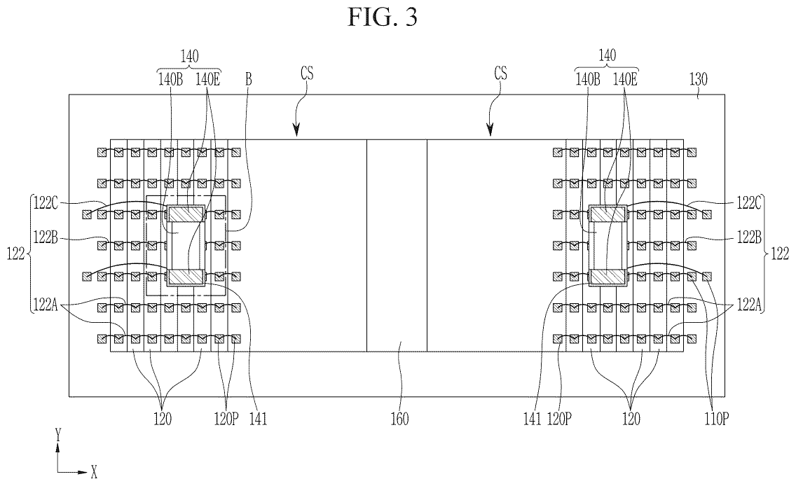

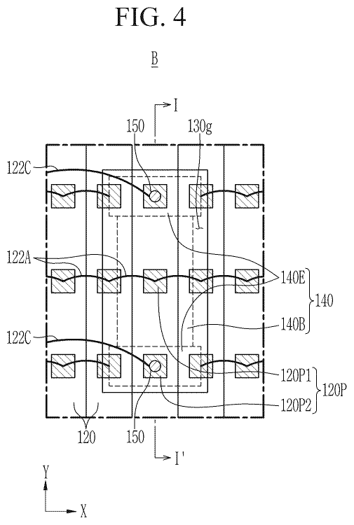

To clearly illustrate the layout of connection pads and conductive wires, the encapsulant 130 is assumed to be transparent in FIGS. 3 and 4.

The substrate 110 may be a printed circuit board (PCB).

On an upper surface of the substrate 110, there may be pads 110P for electrical connection with other components mounted on the substrate 110, such as the chip stacking structure CS and the semiconductor chip 160. The pads 110P may each be bonded to a conductive wire 122 and electrically connected to a wiring layer of the substrate 110. The material of the pad 110P may be a conductive material such as copper (Cu), aluminum (Al), nickel (Ni), gold (Au), silver (Ag), palladium (Pd), titanium (Ti), or an alloy thereof.

The chip stacking structure CS is disposed on the substrate 110 and electrically connected to the substrate 110, and may include a plurality of stacked semiconductor chips 120.

The number of chip stacking structures CS disposed on the substrate 110 is not particularly limited and may be more or less than that shown in the drawings. For example, only a single chip stacking structure CS may be disposed on the substrate 110, or four, six, or more chip stacking structures CS may be so disposed.

The number of semiconductor chips 120 included in the chip stacking structure CS is not particularly limited and may be more or less than that shown in the drawings. For example, a chip stacking structure CS may include four, sixteen, or thirty-two stacked semiconductor chips 120.

Each semiconductor chip 120 may include connection pads 120P. The connection pads 120P may be arranged to deviate toward one edge of each semiconductor chip 120. For example, the connection pads 120P may be arranged in a first direction, e.g., the Y direction (Y).

The conductive wire 122 and/or the conductive pillar 150 may be connected to the connection pad 120P. For connection of the conductive wire 122 and/or the conductive pillar 150, the semiconductor chips 120 may be stacked in an offset manner so that the connection pads 120P are not covered by other semiconductor chips 120. For example, the semiconductor chips 120 may be stacked with their edges offset in a second direction perpendicular to the first direction, e.g., the X direction (X).

The semiconductor chip 120 may be disposed so that the surface on which the connection pad 120P is disposed faces the groove portion 130g in a vertical direction. In other words, the semiconductor chip 120 may be disposed so that the surface opposite to the surface on which the connection pad 120P is disposed faces the substrate 110 in the vertical direction.

The material of the connection pad 120P may be a conductive material such as copper (Cu), aluminum (Al), nickel (Ni), gold (Au), silver (Ag), palladium (Pd), titanium (Ti), or an alloy thereof.

Some of the connection pads 120P may be connected to the passive element 140 through the conductive pillar 150. In some embodiments, among the connection pads 120P, the connection pad 120P that is not connected to the conductive pillar 150 and the passive element 140 may be referred to as a first connection pad 120P1 and the connection pad 120P that is connected to the passive element 140 through the conductive pillar 150 may be referred to a second connection pad 120P2.

The semiconductor chip 120 may include a memory chip. The memory chips may be stacked in the vertical direction to form memory devices such as 3D NAND flash memory, high bandwidth memory (HBM), and 3D DRAM.

Each semiconductor chip 120 may be attached to another semiconductor chip 120 or the substrate 110 through an adhesive member 121. In other words, the adhesive member 121 may be disposed between the chip stacking structure CS (the lowest semiconductor chip among the semiconductor chips 120 of the chip stacking structure CS) and the substrate 110, and between the semiconductor chips 120. For example, the adhesive member 121 may be attached to another semiconductor chip 120 or the substrate 110 while being attached to a lower surface (in the vertical direction) of the semiconductor chip 120.

An adhesive material such as a die attach film (DAF) may be used as the material of the adhesive member 121.

Each semiconductor chip 120 may be electrically connected to the substrate 110 and/or another semiconductor chip 120. In an embodiment, each semiconductor chip 120 may have the conductive wire 122 bonded thereto that connects the semiconductor chip 120 to the substrate 110 or to another semiconductor chip 120. The conductive wire 122 may be connected to the connection pad 120P of the semiconductor chip 120 and embedded in the encapsulant 130.

A first conductive wire 122A may connect the first connection pads 120P1 of the semiconductor chips 120 to each other. A second conductive wire 122B may connect the first connection pads 1 20P1 of the semiconductor chip 120 to the substrate 110. For example, the first conductive wires 122A may connect the first connection pads 120P1 of the adjacent semiconductor chips 120 to each other and the second conductive wires 122B may connect the first connection pad 120P1 of the lowest semiconductor chip among the semiconductor chips 120 to the substrate 110.

A third conductive wire 122C may electrically connect the second connection pad 120P2, the passive element 140, and the substrate 110. The third conductive wire 122C may be a long wire having a longer length than the first conductive wire 122A and the second conductive wire 122B. By connecting the second connection pad 120P2 to the substrate 110 through the third conductive wire 122C, the electrical connection path between the passive element 140 and the substrate 110 may be minimized. In some embodiments, the second connection pad 120P2 may be connected to the substrate 110 via the semiconductor chips 120 through the second conductive wire 122B and the first conductive wire 122A.

The material of the conductive wires 122 may be a conductive material such as copper (Cu), aluminum (Al), nickel (Ni), gold (Au), silver (Ag), palladium (Pd), titanium (Ti), or an alloy thereof.

In addition to the conductive wire 122, each semiconductor chip 120 may be electrically connected to the substrate 110 and/or another semiconductor chip 120 through other components such as a through silicon via (TSV); not shown in the figures.

The encapsulant 130 may cover at least a portion of each of the chip stacking structure CS, the conductive wire 122, and the conductive pillar 150.

The groove portion 130g for disposing the passive element 140 may be formed in the encapsulant 130. The groove portion 130g may include a bottom surface bs and a wall surface ws extending in the vertical direction, e.g., the Z direction (Z), perpendicular to the bottom surface bs. The passive element 140 may be disposed on the bottom surface bs of the groove portion 130g and surrounded by the wall surface ws.

The groove portion 130g may be formed by removing a portion of the encapsulant 130 in the vertical direction from an upper surface of the encapsulant 130 toward the bottom surface bs of the groove portion 130g. When forming the groove portion 130g, the encapsulant 130 may be processed using a mechanical drill, laser, or similar cutting methods.

At least a portion of the groove portion 130g may be positioned on the chip stacking structure CS. For example, at least a portion of the groove portion 130g may be positioned on the semiconductor chip 120 connected to the conductive pillar 150. Accordingly, the passive element 140 and the semiconductor chip 120 disposed within the groove portion 130g may be connected by a short path through the conductive pillar 150.

The groove portion 130g may have a first cross-sectional width w1 in the second direction (e.g., the X direction) and a second cross-sectional width w5 in the first direction (e.g., the Y direction). The passive element 140 may have a first cross-sectional width w2 in the second direction (e.g., the X direction) and a second cross-sectional width w6 in the first direction (e.g., the Y direction). In some embodiments, the first width w1 may be greater than or equal to the first width w2. In some embodiments, the second width w5 may be greater than or equal to the second width w6. As used herein, the cross-sectional width means the width in the X direction (X) in the X-Z plane or the width in the Y direction (Y) in the Y-Z plane.

For example, the cross-sectional widths w1 and w5 of the groove portion 130g may be slightly larger than the cross-sectional widths w2 and w6 of the passive element 140, and the passive element 140 may be inserted into the groove portion 130g so as to be aligned with the conductive pillar 150. Alternatively, the cross-sectional widths w1 and w5 of the groove portion 130g may be the same as the cross-sectional widths w2 and w6 of the passive element 140, and the passive element 140 may fit snugly into the groove portion 130g.

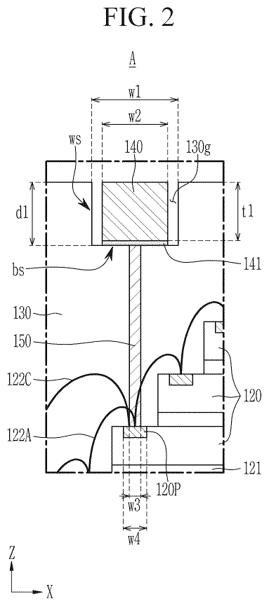

A depth d1 of the groove portion 130g in the vertical direction may be greater than or equal to a thickness t1 of the passive element 140 in the vertical direction (see FIG. 2). By forming the depth d1 of the groove portion 130g to be greater than or equal to the thickness t1 of the passive element 140, the passive element 140 may be entirely disposed within the groove portion 130g, and the overall thickness of the semiconductor package may not increase due to the passive element 140. When a conductive member 141 is present on a lower surface of the passive element 140, the depth d1 of the groove portion 130g may be greater than the sum of the thickness t1 of the passive element 140 and a thickness of the conductive member 141. In some embodiments, the depth d1 of the groove portion 130g may be less than the thickness t1 of the passive element 140 and a portion of the passive element 140 (for example, an upper end) may protrude above the encapsulant 130 in the vertical direction.

As a material for the encapsulant 130, an insulating material such as polyimide, epoxy, or epoxy molding compound (EMC) may be used. In some embodiments, the encapsulant 130 may further include a filler such as silica or alumina dispersed in the insulating material.

The passive element 140 may be inserted into the groove portion 130g so that at least a portion thereof is positioned within the groove portion 130g.

The passive element 140 may be a multi-layer ceramic capacitor (MLCC), but may also be another type of capacitor, such as a tantalum capacitor, or another type of passive element, such as an inductor or a resistor.

The passive element 140 may include a body 140B and an external electrode 140E.

The body 140B may be a dielectric body formed by stacking dielectric sheets, such as ceramic green sheets. Internal electrodes connected to external electrodes 140E may be printed on an inside of the body 140B.

The external electrode 140E may include a first external electrode and a second external electrode disposed at both ends of the body 140B along the first direction (e.g., the Y direction). Each external electrode 140E may be electrically connected to the second connection pad 120P2 of the semiconductor chip 120 through a corresponding conductive pillar 150 and may also be electrically connected to the substrate 110 through the third conductive wire 122C. One of the external electrodes 140E may be electrically connected to a power wiring of the substrate 110, and the other external electrode 140E may be electrically connected to a ground wiring of the substrate.

The external electrode 140E may include a conductive material such as tin (Sn), copper (Cu), aluminum (Al), nickel (Ni), gold (Au), silver (Ag), palladium (Pd), titanium (Ti), or an alloy thereof. In some embodiments, the external electrode 140E may include a plurality of layers.

The passive element 140 may be connected to the conductive pillar 150 through the conductive member 141 (the conductive member 141 is omitted in FIG. 4). The conductive member 141 may fill at least a portion of the space between the external electrode 140E of the passive element 140 and the conductive pillar 150, and may extend over the external side surface of the external electrode 140E along the first direction and the second direction.

The conductive member 141 may be formed, for example, of solder paste, and may be formed by applying solder paste to the external electrode 140E, placing the passive element 140 on the conductive pillar 150, and then melting and cooling the solder paste through a solder reflow process.

The conductive member 141 may have a visible boundary with the external electrode 140E. In some embodiments, the conductive member 141 may be integrated with the external electrode 140E and may not have a visible boundary.

The conductive pillar 150 may be at least partially embedded in the encapsulant 130 to electrically connect one of the semiconductor chips 120 to the passive element 140. For example, one end (e.g., the lower end in the vertical direction) of the conductive pillar 150 may be embedded in the encapsulant 130 and connected to the second connection pad 120P2 of the semiconductor chip 120, and the other end (e.g., the upper end in the vertical direction) of the conductive pillar 150 may be exposed to the groove portion 130g and connected to the external electrode 140E of the passive element 140.

The conductive pillar 150 may extend in the vertical direction from the semiconductor chip 120 toward the passive element 140 and overlap the semiconductor chip 120 and the passive element 140 in the vertical direction, thus connecting the passive element 140 and the semiconductor chip 120 by a shortest path.

The conductive pillar 150 may be embedded in the encapsulant 130 and then exposed through the groove portion 130g when the groove portion 130g is formed. When forming the groove portion 130g, a portion of the conductive pillar 150 may be removed together with the encapsulant 130. The end of the conductive pillar 150 connected to the passive element 140 may be positioned at the same level in the vertical direction as the bottom surface bs of the groove portion 130g. Alternatively, when forming the groove portion 130g, the conductive pillar 150 may remain without being removed, and the end of the conductive pillar 150 connected to the passive element 140 may be positioned at a level higher in the vertical direction than the bottom surface bs of the groove portion 130g. In some embodiments, the end of the conductive pillar 150 connected to the passive element 140 may be positioned at a level lower in the vertical direction than the bottom surface bs of the groove portion 130g and exposed above the encapsulant 130.

The conductive pillar 150 may have a cross-sectional width w3 in the second direction (e.g., the X direction) which may be less than or equal to a cross-sectional width w4 in the second direction (e.g., the X direction) of the second connection pad 120P2 (see FIG. 2). By forming the cross-sectional width w3 of the conductive pillar 150 to be less than or equal to the cross-sectional width w4 of the second connection pad 120P2, a space for disposing the third conductive wire 122C on the second connection pad 120P2 may be provided.

The material of the conductive pillar 150 may be a conductive material such as copper (Cu), aluminum (Al), nickel (Ni), gold (Au), silver (Ag), palladium (Pd), titanium (Ti), or an alloy thereof.

The semiconductor chip 160 may be disposed on the substrate 110 and electrically connected to the substrate 110.

The semiconductor chip 160 may be attached to the substrate 110 through an adhesive member 161 and connected to the substrate 110 through a conductive wire 162.

The semiconductor chip 160 may also include connection pads 160P. The semiconductor chip 160 may be disposed so that the surface opposite to the surface on which the connection pad 160P is disposed (in the vertical direction) faces the substrate 110, and the conductive wire 162 may be connected to the connection pad 160P.

The semiconductor chip 160 may include, for example, a controller chip.

In the semiconductor package industry, a multi-layer ceramic capacitor (MLCC) may be mounted side by side with a semiconductor chip on a substrate to improve signal quality, and the MLCC may be connected to the semiconductor chip through the substrate. When mounting the MLCC on a substrate, space for mounting the MLCC is needed and it may be difficult to utilize the MLCC mounting space as a wiring space.

According to some embodiments, since the passive element 140 is disposed within the groove portion 130g of the encapsulant 130, no space on the substrate 110 is needed for mounting the passive element 140, so that the signal quality of the semiconductor package may be improved without increasing the size. In addition, the entire region of the substrate 110 may be utilized as a wiring space, thereby increasing the freedom of wiring design. In addition, it may be possible to provide a semiconductor package having low inductance by connecting the passive element 140 and the semiconductor chip 120 with a short electrical path through the conductive pillar 150.

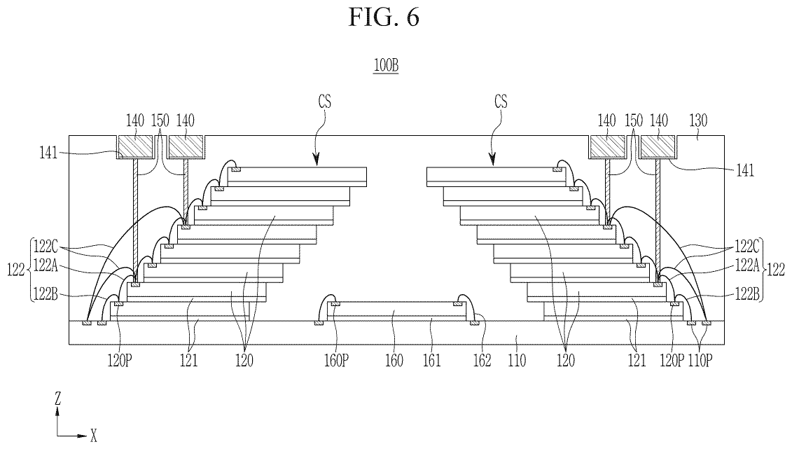

Referring to FIG. 6, in a semiconductor package 100B, a plurality of passive elements 140 may be connected to each chip stacking structure CS. Each passive element 140 may be disposed within the groove portion 130g and connected to the semiconductor chip 120 through the conductive pillar 150. The passive elements 140 may be individually connected to different semiconductor chips 120 or may be connected together to the same semiconductor chip 120. In some embodiments, the passive elements 140 may be disposed within different groove portions 130g to prevent electrical shorting between them or may be spaced apart from each other along the second direction (e.g., the X direction) within the same groove portion 130g.

The description of the semiconductor package 100A may be equally applied to the description of the configuration shown in FIG. 6.

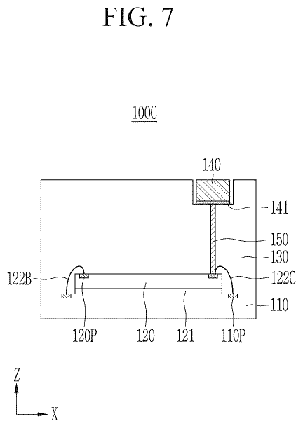

Referring to FIG. 7, a semiconductor package 100C may include a single semiconductor chip 120. The semiconductor chip 120 may be disposed on the substrate 110 and electrically connected to the substrate 110 through the conductive wires 122B and 122C, and may also be electrically connected to the passive element 140 disposed within the groove portion 130g through the conductive pillar 150.

The description of the semiconductor package 100A may be equally applied to the description of the configuration shown in FIG. 7.

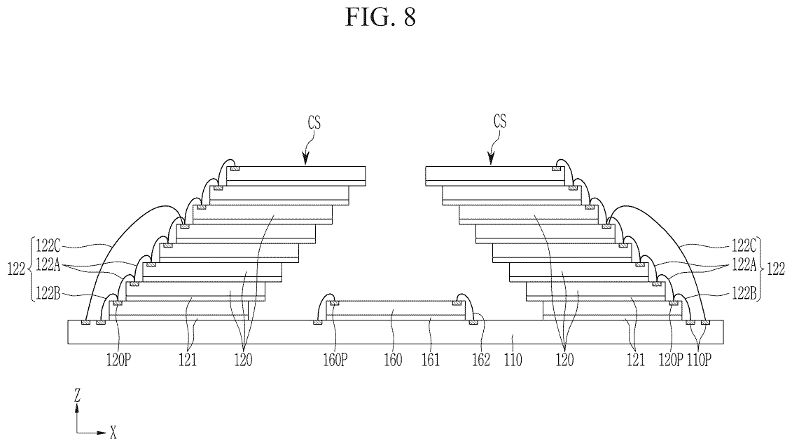

FIGS. 8 to 12 are manufacturing process diagrams of the semiconductor package shown in FIG. 1.

Referring to FIG. 8, the chip stacking structures CS and semiconductor chips 120 and 160 may be disposed on the substrate 110. The semiconductor chips 120 and 160 may be connected to the substrate 110 using the conductive wires 122.

The chip stacking structure CS and the semiconductor chips 120, 160 may be affixed to the substrate 110 through the adhesive members 121 and 161. Additionally, the semiconductor chips 120 of the chip stacking structure CS may be attached to each other through the adhesive member 121.

The chip stacking structure CS may be formed by sequentially stacking the semiconductor chips 120 on the substrate 110 in the vertical direction, may be formed by stacking modules in which the plurality of semiconductor chips 120 (e.g., four semiconductor chips 120) are stacked on the substrate 110, or may be formed separately and disposed on the substrate 110.

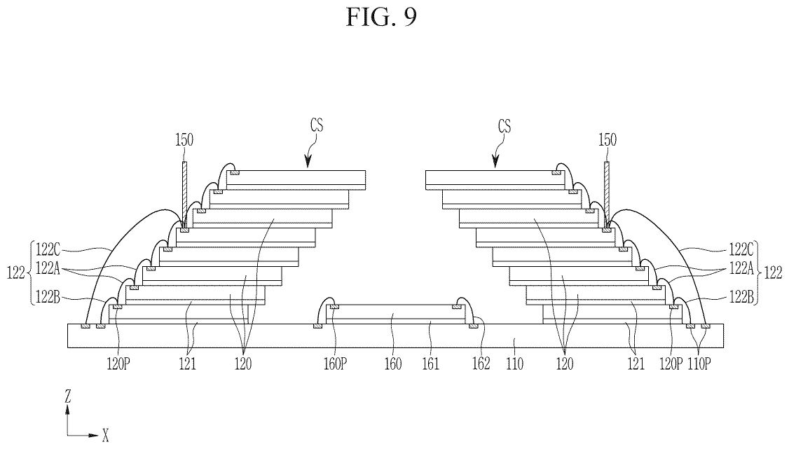

Referring to FIG. 9, the conductive pillar 150 connected to the connection pad 120P may be formed on the connection pad 120P of the semiconductor chip 120. The conductive pillar 150 may be formed to extend in the vertical direction from the semiconductor chip 120.

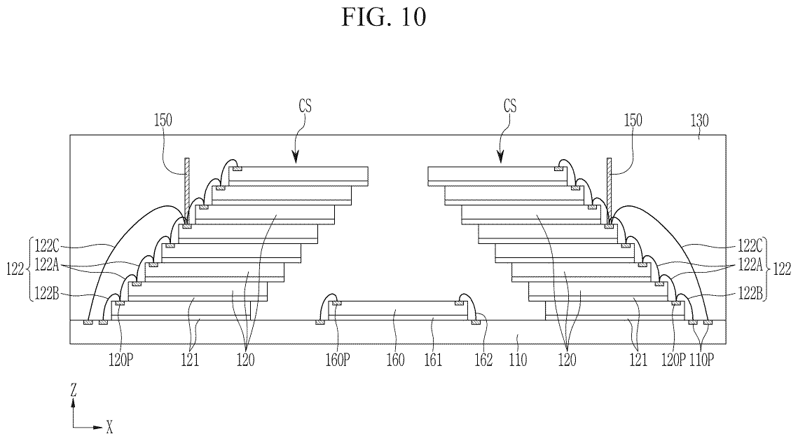

Referring to FIG. 10, the chip stacking structures CS, the semiconductor chips 120, 160, the conductive wires 122, and the conductive pillars 150 may be sealed with the encapsulant 130. After the encapsulant 130 is formed, the upper end of the conductive pillar 150 in the vertical direction may be covered with the encapsulant 130. The encapsulant 130 may be formed by compression molding, transfer molding, or similar deposition methods.

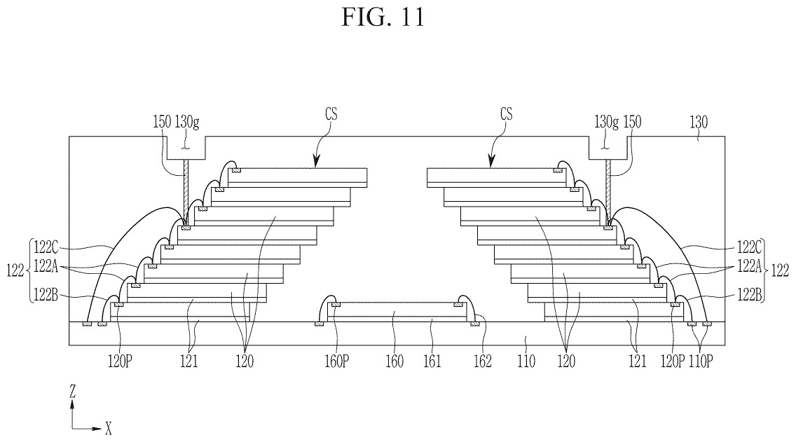

Referring to FIG. 11, the groove portion 130g may be formed in the encapsulant 130 to expose the conductive pillar 150. The groove portion 130g may be formed, for example, by removing a portion of the encapsulant 130 in the vertical direction from the upper surface of the encapsulant 130 toward the substrate 110. When forming the groove portion 130g, the encapsulant 130 may be processed using a mechanical drill, laser, or similar cutting methods. When forming the groove portion 130g, a portion of the conductive pillar 150 may be removed together with the encapsulant 130 or may remain without being removed.

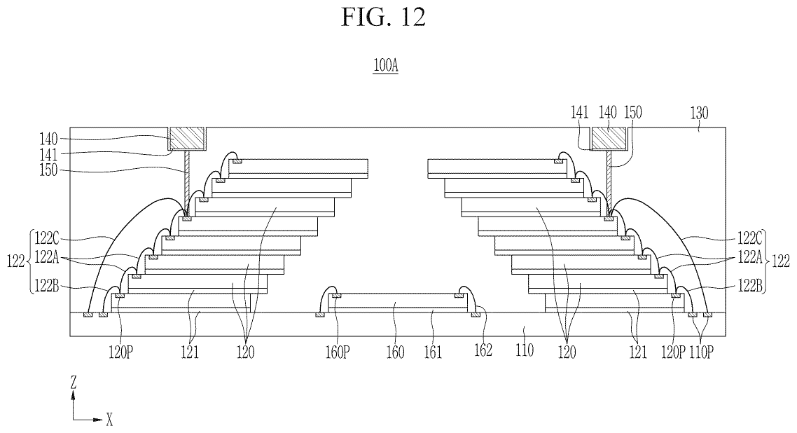

Referring to FIG. 12, the passive element 140 may be disposed within the groove portion 130g and connected to the conductive pillar 150.

Depending on the size of the groove portion 130g, the passive element 140 may be inserted into the groove portion 130g so as to be aligned with the conductive pillar 150, or may be fitted snugly into the groove portion 130g.

The passive element 140 may be connected to the conductive pillar 150 by the conductive member 141. The conductive member 141 may be formed, for example, of solder paste, and may be formed by applying solder paste to the external electrode 140E, placing the passive element 140 on the conductive pillar 150, and then melting and cooling the solder paste through a solder reflow process.

While the embodiments of the present disclosure have been described in detail, it is to be understood that the disclosure is not limited to the disclosed embodiments, but is intended to cover various modifications and equivalent arrangements included within the scope of the appended claims.

In addition, the embodiments of the present disclosure are not independent of each other and may be implemented in combination with each other unless they are specifically contradictory. Accordingly, combinations of embodiments should also be considered as being included in the present disclosure.

What is claimed is:

1. A semiconductor package, comprising:
a substrate;
a semiconductor chip disposed on the substrate and electrically connected to the substrate;
an encapsulant covering at least a portion of the semiconductor chip, wherein:
the encapsulant includes a groove portion; and
at least a portion of the groove portion is disposed above the semiconductor chip;
a passive element disposed at least partially within the groove portion; and
a conductive pillar embedded at least partially in the encapsulant and electrically connecting the semiconductor chip and the passive element.

2. The semiconductor package of claim 1, wherein a cross-sectional width of the groove portion in a first direction perpendicular to a vertical direction is greater than or equal to a cross-sectional width of the passive element in the first direction.

3. The semiconductor package of claim 1, wherein a depth of the groove portion in a vertical direction is greater than or equal to a thickness of the passive element in the vertical direction.

4. The semiconductor package of claim 1, wherein one end of the conductive pillar in a vertical direction is exposed to the groove portion and is connected to the passive element.

5. The semiconductor package of claim 4, wherein:
the groove portion includes a bottom surface; and
one end of the conductive pillar is positioned at a level in the vertical direction equal to or higher than the bottom surface.

6. The semiconductor package of claim 1, wherein:
the semiconductor chip includes a connection pad;
the conductive pillar is connected to the connection pad; and
a cross-sectional width of the conductive pillar in a first direction perpendicular to a vertical direction is less than or equal to a cross-sectional width of the connection pad in the first direction.

7. The semiconductor package of claim 1, wherein the conductive pillar overlaps the semiconductor chip and the passive element in a vertical direction.

8. The semiconductor package of claim 1, further comprising:
a conductive member disposed between the passive element and the conductive pillar, the conductive member connecting the passive element and the conductive pillar.

9. The semiconductor package of claim 1, further comprising:
a conductive wire electrically connecting the semiconductor chip to the substrate.

10. The semiconductor package of claim 1, further comprising:
an adhesive member disposed between the substrate and the semiconductor chip.

11. A semiconductor package, comprising:
a substrate;
a semiconductor chip disposed on the substrate and including a first connection pad, a second connection pad, and a third connection pad;
an encapsulant covering at least a portion of the semiconductor chip, wherein:
the encapsulant includes a groove portion; and
at least a portion of the groove portion is disposed above the semiconductor chip;
a passive element disposed at least partially within the groove portion, the passive element including a first external electrode and a second external electrode;
a first conductive wire embedded at least partially in the encapsulant and electrically connecting the first connection pad to the substrate;
a first conductive pillar embedded at least partially in the encapsulant and electrically connecting the second connection pad to the first external electrode; and
a second conductive pillar embedded at least partially in the encapsulant and electrically connecting the third connection pad to the second external electrode.

12. The semiconductor package of claim 11, wherein:
the first external electrode is electrically connected to a power wiring of the substrate; and
the second external electrode is electrically connected to a ground wiring of the substrate.

13. The semiconductor package of claim 11, further comprising:
a second conductive wire electrically connecting the second connection pad to the substrate; and
a third conductive wire electrically connecting the third connection pad to the substrate.

14. The semiconductor package of claim 11, wherein the passive element is a multi-layer ceramic capacitor.

15. The semiconductor package of claim 11, wherein the semiconductor chip is oriented such that a surface on which the first connection pad, the second connection pad, and the third connection pad are disposed faces the groove portion.

16. A semiconductor package, comprising:
a substrate;
a chip stacking structure disposed on the substrate and including a plurality of stacked first semiconductor chips;
an encapsulant covering at least a portion of the chip stacking structure, wherein the encapsulant includes a groove portion at least partially disposed above the chip stacking structure;
a passive element disposed at least partially within the groove portion; and
a conductive pillar embedded at least partially in the encapsulant and electrically connecting one of the first semiconductor chips to the passive element.

17. The semiconductor package of claim 16, wherein:
one of the first semiconductor chips includes a first connection pad;
the conductive pillar is connected to the first connection pad; and
the semiconductor package further includes a first conductive wire electrically connecting the first connection pad and the substrate.

18. The semiconductor package of claim 17, wherein the one of the first semiconductor chips includes a second connection pad, the semiconductor package further comprising:
a second conductive wire electrically connecting the second connection pad to another one of the first semiconductor chips.

19. The semiconductor package of claim 16, further comprising:
a second semiconductor chip disposed side by side with the chip stacking structure on the substrate in a first direction perpendicular to a vertical direction.

20. The semiconductor package of claim 19, wherein:
the first semiconductor chip comprises a memory chip; and
the second semiconductor chip comprises a controller chip.
